(19) United States
(12) Patent Application Publication
(10) Pub. No.: US 2024/0295211 A1
(43) Pub. Date: Sep. 5, 2024

(54) SYSTEMS AND METHODS FOR CONTROLLING AN INDUSTRIAL ASSET OF AN ASSET FAMILY

(71) Applicant: General Electric Company, Schenectady, NY (US)

(72) Inventors: Abhay Harpale, San Ramon, CA (US); Pranav Agarwal, Newark, CA (US); Justin Edwin Barton, Glenville, NY (US)

(21) Appl. No.: 18/574,799

(22) PCT Filed: Jun. 29, 2021
(86) PCT No.: PCT/US2021/039555

§ 371 Date: Dec. 28, 2023

(51) Int. Cl. F03D 7/04; F03D 17/00; G01M 13/028; G01M 13/045

(52) U.S. Cl. CPC F03D 7/046; F03D 17/014; G01M 13/028; G01M 13/045; F05B 2260/80

(57) ABSTRACT

Systems and methods are provided for the control of an industrial asset, such as a power generating asset, of an asset family. Accordingly, a plurality of frequency-parameter pairings corresponding to at least one power spectral density of the industrial asset are determined. A deviation score for each of the plurality of frequency-parameter pairings is then determined. Based, at least in part, on the deviation score, a multi-variate anomaly score is determined. Additionally, a fault probability for the industrial asset is determined based, at least in part, on the multi-variate anomaly score. A control action is then implemented based on the fault probability exceeding a fault threshold.

### FIELD

The present disclosure relates in general to industrial assets, and more particularly to systems and methods for the control of an industrial asset of an asset family based on fault detection via power spectral density indications.

### BACKGROUND

As disclosed herein, industrial assets may take a variety of forms. Accordingly, the industrial asset may include assets directed to the aviation industry, the nuclear industry, the petroleum industry, industrial infrastructure (e.g., pipelines and/or pumping stations), and/or the power generation industry. For example, the industrial asset may be a power generating asset and may include assets which rely on renewable and/or nonrenewable sources of energy.

Those power generating assets which rely on renewable sources of energy may generally be considered one of the cleanest, most environmentally friendly energy sources presently available. For example, wind turbines have gained increased attention in this regard. A modern wind turbine typically includes a tower, a generator, a gearbox, a nacelle, and one or more rotor blades. The nacelle includes a rotor assembly coupled to the gearbox and to the generator. The rotor assembly and the gearbox are mounted on a bedplate support frame located within the nacelle. The rotor blades capture kinetic energy of wind using known airfoil principles. The rotor blades transmit the kinetic energy in the form of rotational energy so as to turn a shaft coupling the rotor blades to a gearbox, or if a gearbox is not used, directly to the generator. The generator then converts the mechanical energy to electrical energy and the electrical energy may be transmitted to a converter and/or a transformer housed within the tower and subsequently deployed to a utility grid. Modern wind power generation systems typically take the form of a wind farm having multiple wind turbine generators that are operable to supply power to a transmission system providing power to a power grid.

During operations, the various components of the industrial asset may develop faults. When detected, the fault(s) may be addressed via a maintenance activity and/or a controlling of the industrial asset. As such, it may be desirable to reliably detect fault conditions in order to preclude further wearing of the component and/or the industrial asset. However various faults, such as cracks in rotor blades of the wind turbine, may be difficult to detect during the normal operations of the industrial asset.

Thus, the art is continuously seeking new and improved systems and methods that address the aforementioned issues. As such, the present disclosure is directed to systems and methods controlling an industrial asset of an asset family in the presence of a fault condition.

### BRIEF DESCRIPTION

Aspects and advantages of the invention will be set forth in part in the following description, or may be obvious from the description, or may be learned through practice of the invention.

In one aspect, the present disclosure is directed to a method for controlling an industrial asset of an asset family having a plurality of industrial assets. The method may include determining, via a controller, a plurality of frequency-parameter pairings corresponding to at least one power spectral density of the industrial asset. Each frequency-parameter pairing may include an energy-level distribution for a parameter of the industrial asset across a plurality of frequency intervals of a portion of the at least one power spectral density. The method may also include determining, via the controller, a deviation score for each of the plurality of frequency-parameter pairings. Each of the deviation scores may be indicative of a magnitude difference between the energy-level distribution of each frequency-parameter pairing and a corresponding energy-level distribution of a nominal frequency-parameter pairing of the asset family. Additionally, the method may include determining, via the controller, a multi-variate anomaly score based, at least in part, on the deviation scores. The controller may also determine a fault probability for the industrial asset based, at least in part, on the multi-variate anomaly score. Further, the method may include implementing a control action based on the fault probability exceeding a fault threshold.

In an additional aspect, the present disclosure is directed to a system for controlling an industrial asset of an asset family having a plurality of industrial assets. The system may include at least one sensor operably coupled to the industrial asset and a controller communicatively coupled to the at least one sensor. The controller may include at least one processor configured to perform a plurality of operations. The plurality of operations may include any of the operations and/or features described herein.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 illustrates a perspective view of one embodiment of an industrial asset configured as a wind turbine according to the present disclosure;

FIG. 2 illustrates a perspective, internal view of one embodiment of a nacelle of the wind turbine of FIG. 1 according to the present disclosure:

FIG. 3 illustrates a block diagram of one embodiment of a controller for use with the industrial asset according to the present disclosure:

FIG. 4 illustrates a schematic of a control logic for controlling the industrial asset according to the present disclosure:

FIG. 5 illustrates a schematic of a portion the control logic of FIG. 4 for controlling the industrial asset according to the present disclosure:

FIG. 6 illustrates a power spectral density for a variable of the industrial asset and the asset family according to the present disclosure:

FIG. 7 illustrates a deviation score representing a difference between the power spectral density for the variable of the industrial asset and the asset family in a frequency band according to the present disclosure:

FIG. 8 illustrates a box plot representation of a plurality of statistical distributions of deviation scores for a nominal population and a fault population of the asset family according to the present disclosure; and

FIG. 9 illustrates a fault-probability profile for the asset family according to the present disclosure.

Repeat use of reference characters in the present specification and drawings is intended to represent the same or analogous features or elements of the present invention.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

As used herein, the terms “first”, “second”, and “third” may be used interchangeably to distinguish one component from another and are not intended to signify location or importance of the individual components.

The terms “coupled,” “fixed,” “attached to,” and the like refer to both direct coupling, fixing, or attaching, as well as indirect coupling, fixing, or attaching through one or more intermediate components or features, unless otherwise specified herein.

Approximating language, as used herein throughout the specification and claims, is applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value, or the precision of the methods or machines for constructing or manufacturing the components and/or systems. For example, the approximating language may refer to being within a 10 percent margin.

Here and throughout the specification and claims, range limitations are combined and interchanged, such ranges are identified and include all the sub-ranges contained therein unless context or language indicates otherwise. For example, all ranges disclosed herein are inclusive of the endpoints, and the endpoints are independently combinable with each other.

Generally, the present disclosure is directed to systems and methods for controlling an industrial asset of an asset family. For example, the systems and methods disclosed herein may be employed to control a wind turbine which is a specific wind turbine model/platform (e.g., GE's 3MW-117, 3MW-130, or 3MW-137 families of wind turbines). In particular, the systems and methods disclosed herein may be employed to detect a fault within the industrial asset and to take a control action in response to the fault detection.

According to the present disclosure, any given parameter (e.g., a rotational speed, a vibration, a bending moment, an acceleration, an acoustic signature, etc.) of the industrial asset may be reflected by a number of time-series observations received from a corresponding sensor. These observations may be converted into a power spectral density for the parameter. The power spectral density may reflect a range of energy levels of the sensor signal at each of a number of frequency intervals. The range of energy levels may correspond to various operating conditions of the industrial asset. Because the industrial assets of the asset family may have substantially similar components, the asset family may have a nominal power spectral density which reflects the parameter when the industrial asset is in a nominal state (e.g. healthy industrial assets). However, the power spectral density of a faulty unit may be different from that of healthy units of the family for certain parameters at certain frequencies.

In order to detect a fault, the distance between the power spectral density of a potentially faulty unit and the power spectral density of the asset family may be calculated for each parameter at each frequency. The resultant frequency-parameter pairings may then be inspected to determine which of the frequency-parameter pairings may be indicative of a fault condition. The differences between the magnitude of each frequency-parameter pairing of the potentially faulty industrial asset and the magnitude of the corresponding frequency-parameter pairing of the asset family may be reflected in a deviation score. The various deviation scores may be combined into a multi-variate anomaly score for the industrial asset. The multi-variate anomaly score may be employed to determine a fault probability for the industrial asset. When the fault probability exceeds a fault threshold, a control action may be implemented.

The systems and methods disclosed herein may, for example, be employed to detect faults in a wind turbine. The power spectral density of a wind turbine having a blade with a crack may be different than the nominal power spectral density for the wind turbine platform. Accordingly, the systems and methods disclosed herein may be employed to detect cracks and blades which may otherwise go undetected. Additionally, the systems and methods disclosed herein may, for example be particularly well-suited to detect cracks, wearing, and/or lubrication failures in additional components of a wind turbine, such as the gearbox, the main bearing, the pitch bearings, the pitch motors, the yaw bearing, the yaw motors, the generator bearings and/or other similar components.

It should be appreciated that the detection of the fault in the industrial asset may be desirable for multiple reasons. Namely, the detection of a fault may preclude the accumulation of additional wear to the industrial asset by facilitating a maintenance activity and/or a controlling of the industrial asset (e.g., derating, service-time limitations, etc). For example, the detection of a defect in a rotor blade or bearing may facilitate the servicing of the rotor blade or bearing prior to blade/bearing failure, which may prevent a more catastrophic accumulation of damage. Additionally, the detection of the fault via the power spectral density may facilitate the identification of a component of the industrial asset to which the fault may be attributed. This identification may, for example, preclude the replacement of components having additional serviceable life and may, therefore, reduce service and/or maintenance costs.

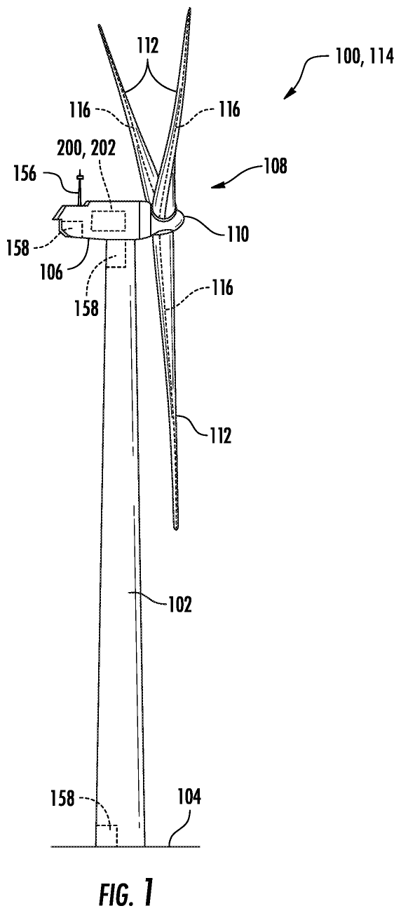

Referring now to the drawings, FIG. 1 illustrates a perspective view of one embodiment of an industrial asset 100 according to the present disclosure. As shown, the industrial asset 100 may be configured as a power generating asset, such as a wind turbine 114. In an additional embodiment, when configured as a power generating asset, the industrial asset 100 may, for example, be configured as a solar power generating asset, a hydroelectric plant, a fossil fuel generator, and/or a hybrid power generating asset. However, in further embodiments, the industrial asset 100 may be configured as an electrical grid, a pumping station, a pipeline, a refinery, a nuclear facility, an aviation asset, and/or other similar asset.

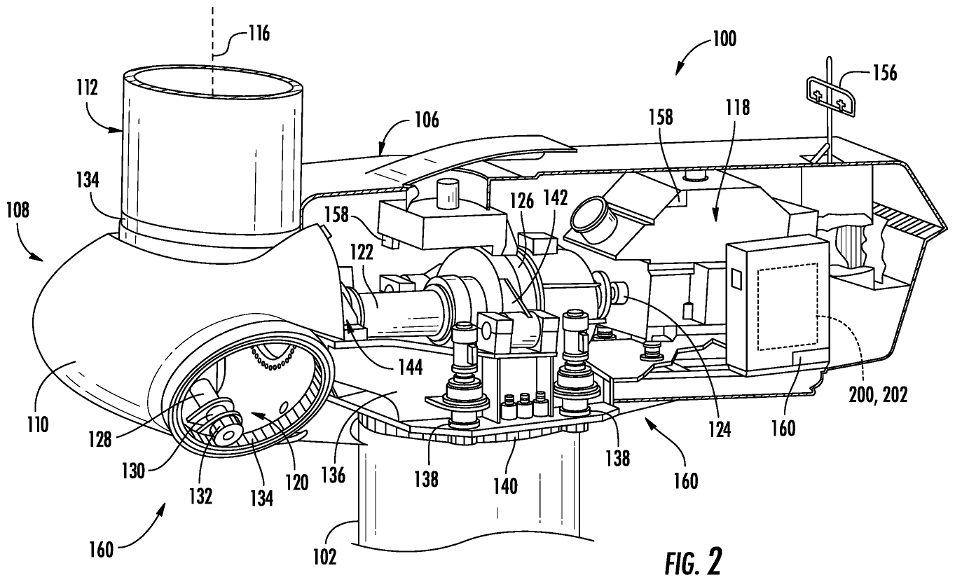

When configured as a wind turbine 114, the industrial asset 100 may generally include a tower 102 extending from a support surface 104, a nacelle 106, mounted on the tower 102, and a rotor 108 coupled to the nacelle 106. The rotor 108 may include a rotatable hub 110 and at least one rotor blade 112 coupled to, and extending outwardly from, the hub 110. For example, in the illustrated embodiment, the rotor 108 includes three rotor blades 112. However, in an additional embodiment, the rotor 108 may include more or less than three rotor blades 112. Each rotor blade 112 may be spaced about the hub 110 to facilitate rotating the rotor 108 to enable kinetic energy to be transferred from the wind into usable mechanical energy, and subsequently, electrical energy. For instance, the hub 110 may be rotatably coupled to an electric generator 118 (FIG. 2) positioned within the nacelle 106 to permit electrical energy to be produced.

The industrial asset 100 may also include a controller 200. When configured as a wind turbine 114, the controller 200 may be configured as a turbine controller centralized within the nacelle 106. However, in other embodiments, the controller 200 may be located within any other component of the wind turbine 114 or at a location outside the wind turbine. Further, the controller 200 may be communicatively coupled to any number of the components of the industrial asset 100 in order to control the components. As such, the controller 200 may include a computer or other suitable processing unit. Thus, in several embodiments, the controller 200 may include suitable computer-readable instructions that, when implemented, configure the controller 200 to perform various different functions, such as receiving, transmitting and/or executing control/command signals. Additionally, the industrial asset 100 may include a plurality of actuators 160 (FIG. 2) which are configured to implement the various command signals and affect an operating state of the industrial asset 100. It should be appreciated that, as used herein, the “operating state” may refer to a physical configuration, orientation, and/or operating status of the industrial asset 100 or a component thereof.

Referring now to FIG. 2, a simplified, internal view of one embodiment of the nacelle 106 of the wind turbine 114 shown in FIG. 1 is illustrated. As shown, the generator 118 may be coupled to the rotor 108 for producing electrical power from the rotational energy generated by the rotor 108. For example, as shown in the illustrated embodiment, the rotor 108 may include a rotor shaft 122 coupled to the hub 110 for rotation therewith. The rotor shaft 122 may be rotatably supported by a main bearing 144. The rotor shaft 122 may, in turn, be rotatably coupled to a high-speed shaft 124 of the generator 118 through a gearbox 126 connected to a bedplate support frame 136. As is generally understood, the rotor shaft 122 may provide a low-speed, high-torque input to the gearbox 126 in response to rotation of the rotor blades 112 and the hub 110. The gearbox 126 may then be configured to convert the low-speed, high-torque input to a high-speed, low-torque output to drive the high-speed shaft 124 and, thus, the generator 118.

Each rotor blade 112 may also include a pitch control mechanism 120 configured to rotate each rotor blade 112 about its pitch axis 116. Each pitch control mechanism 120 may include a pitch drive motor 128, a pitch drive gearbox 130, and a pitch drive pinion 132. In such embodiments, the pitch drive motor 128 may be coupled to the pitch drive gearbox 130 so that the pitch drive motor 128 imparts mechanical force to the pitch drive gearbox 130. Similarly, the pitch drive gearbox 130 may be coupled to the pitch drive pinion 132 for rotation therewith. The pitch drive pinion 132 may, in turn, be in rotational engagement with a pitch bearing 134 coupled between the hub 110 and a corresponding rotor blade 112 such that rotation of the pitch drive pinion 132 causes rotation of the pitch bearing 134. Thus, in such embodiments, rotation of the pitch drive motor 128 drives the pitch drive gearbox 130 and the pitch drive pinion 132, thereby rotating the pitch bearing 134 and the rotor blade(s) 112 about the pitch axis 116.

It should be appreciated that pitching the rotor blade(s) 112 about the pitch axis 116 may alter an angle of attack between the rotor blade(s) 112 and an apparent wind. Accordingly, the rotor blade(s)112 may pitch to feather when the rotor blade(s) 112 rotates about the pitch axis 116 towards alignment with the apparent wind and to power when the rotor blade(s) rotates towards an orientation generally perpendicular to the apparent wind. It should be further appreciated that pitching to feather generally depowers the rotor blade(s) 112 as a result of a reduction in the resultant lift.

Similarly, the wind turbine 114 may include one or more yaw drive mechanisms 138 communicatively coupled to the controller 200, with each yaw drive mechanism(s) 138 being configured to change the angle of the nacelle 106 relative to the wind (e.g., by engaging a yaw bearing 140 of the wind turbine 114). It should be appreciated that the controller 200 may direct the yawing of the nacelle 106 and/or the pitching of the rotor blades 112 so as to aerodynamically orient the wind turbine 114 relative to a wind acting on the wind turbine 114, thereby facilitating power production.

In an embodiment, the industrial asset 100 may include an environmental sensor 156 configured for gathering data indicative of one or more environmental conditions. The environmental sensor 156 may be operably coupled to the controller 200. Thus, in an embodiment, the environmental sensor(s) 156 may, for example, be a wind vane, an anemometer, a lidar sensor, thermometer, barometer, or any other suitable sensor. The data gathered by the environmental sensor(s) 156 may include measures of wind speed, wind direction, wind shear, wind gust, wind veer, atmospheric pressure, and/or ambient temperature. In at least one embodiment, the environmental sensor(s) 156 may be mounted to the industrial asset 100 (e.g., to the nacelle 106 at a location downwind of the rotor 108). For example, the environmental sensor(s) 156 may, in alternative embodiments, be coupled to, or integrated with, the rotor 108 and/or positioned within the nacelle 106.

In an additional embodiment, the environmental sensor(s) 156 may be positioned separate from the industrial asset 100. For example, the environmental sensor(s) 156 may be a meteorological mast displaced some distance from the industrial asset 100. Additionally, the environmental sensor(s) 156 may be coupled to and additional asset, or subsystem of the industrial asset 100, such as a second wind turbine of a wind farm. It should also be appreciated that the environmental sensor(s) 156 may include a network of sensors and may be positioned away from the industrial asset 100.

In addition, the industrial asset 100 may include a at least one operational sensor 158. The operational sensor(s) 158 may be configured to detect a performance of the industrial asset 100, e.g. in response to the environmental condition. For example, the operational sensor(s) 158 may be a rotational speed sensor, a position sensor, an acceleration sensor, and/or an output sensor operably coupled to the controller 200. The operational sensor(s) 158 may be directed at, or integral with, any suitable component of the industrial asset 100. For example, the operational sensor(s) 158 may be directed at the rotor shaft 122 of the wind turbine 114 and/or the generator 118. The operational sensor(s) 158 may gather data indicative of the rotational speed and/or rotational position of the rotor shaft 122, or any other shaft of the industrial asset 100, and thus the rotor 108, or a pump, in the form of a rotor speed, a rotor azimuth, and/or any other suitable measurement. The operational sensor(s) 158 may, in an embodiment, be an analog tachometer, a D.C. tachometer, an A.C. tachometer, a digital tachometer, a contact tachometer a non-contact tachometer, or a time and frequency tachometer. In an embodiment, the operational sensor(s) 158 may, for example, be an encoder, such as an optical encoder. Additionally, the operational sensor(s) 158 may be an ammeter, a voltmeter, an ohmmeter, and/or any other suitable sensor for monitoring an electrical condition of the industrial asset 100. Further, in an embodiment, the operational sensor(s) 158 may be a strain gauge, a proximity sensor, and/or any other suitable sensor configured to detect a displacement of the industrial asset 100 or a component thereof.

It should also be appreciated that, as used herein, the term “monitor” and variations thereof indicates that the various sensors of the industrial asset 100 may be configured to provide a direct measurement of the parameters being monitored or an indirect measurement of such parameters. Thus, the sensors described herein may, for example, be used to generate signals relating to the parameter being monitored, which can then be utilized by the controller 200 to determine a condition or response of the industrial asset 100 and/or a component thereof.

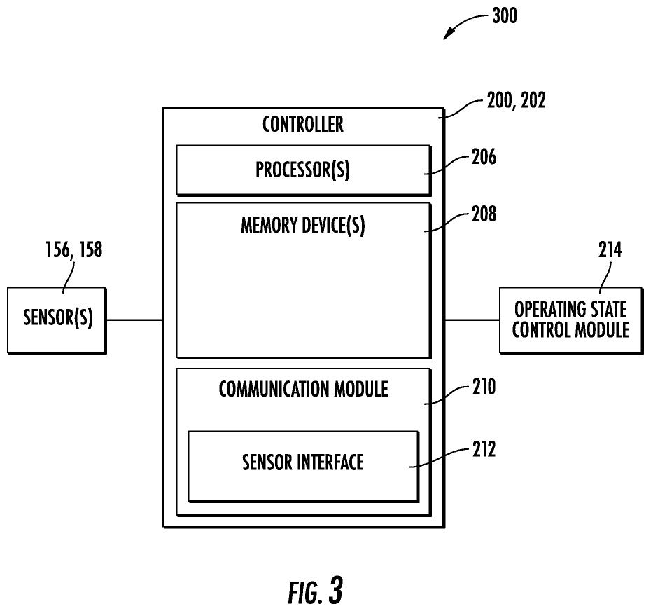

Referring now to FIGS. 3-5 wherein multiple embodiments of a system 300 for controlling the industrial asset 100 according to the present disclosure are presented. As shown particularly in FIG. 3, a schematic diagram of one embodiment of suitable components that may be included within the system 300 is illustrated. For example, as shown, the system 300 may include a controller 200. The controller 200 may be employed to determine a plurality of frequency-parameter pairings 302 and a fault probability 316 corresponding to at least one frequency-parameter pairing 302. Additionally, the controller 200 may be configured as an asset controller 202 (e.g., a turbine controller). As such, the controller 200 may be employed off-line and/or in real time. Additionally, the controller 200 may be a single component located with the industrial asset 100. In an additional embodiment, the controller 200 may encompass more than one component located with the industrial asset 100. In a further embodiment, the controller 200 may include additional components located at a distance from the industrial asset 100.

The controller 200 and/or the asset controller 202 may be communicatively coupled to the environmental sensor(s) 156 and/or the operational sensor(s) 158. Further, as shown, the controller 200 may include one or more processor(s) 206 and associated memory device(s) 208 configured to perform a variety of computer-implemented functions (e.g., performing the methods, steps, calculations and the like and storing relevant data as disclosed herein). Additionally, the controller 200, may also include a communications module 210 to facilitate communications between the controller 200, and the various components of the industrial asset 100. Further, the communications module 210 may include a sensor interface 212 (e.g., one or more analog-to-digital converters) to permit signals transmitted from the sensor(s) 156, 158 to be converted into signals that can be understood and processed by the processors 206. It should be appreciated that the sensor(s) 156, 158 may be communicatively coupled to the communications module 210 using any suitable means. For example, the sensor(s) 156, 158 may be coupled to the sensor interface 212 via a wired connection. However, in other embodiments, the sensor(s) 156, 158 may be coupled to the sensor interface 212 via a wireless connection, such as by using any suitable wireless communications protocol known in the art.

In an embodiment, the communications module 210 may also be operably coupled to an operating state control module 214 so as to implement a control action based on the fault probability 316. For example, the operating state control module 214 may be configured to modify at least one setpoint of the industrial asset 100. Additionally, the communications module 210 may also be operably coupled to at least one actuator 160 configured to implement the control action as directed by a command signal (e.g., a control vector).

As used herein, the term “processor” refers not only to integrated circuits referred to in the art as being included in a computer, but also refers to a controller, a microcontroller, a microcomputer, a programmable logic controller (PLC), an application specific integrated circuit, and other programmable circuits. Additionally, the memory device(s) 208 may generally comprise memory element(s) including, but not limited to, computer readable medium (e.g., random access memory (RAM)), computer readable non-volatile medium (e.g., a flash memory), a floppy disk, a compact disc-read only memory (CD-ROM), a magneto-optical disk (MOD), a digital versatile disc (DVD) and/or other suitable memory elements. Such memory device(s) 208 may generally be configured to store suitable computer-readable instructions that, when implemented by the processor(s) 206, configure the controller 200 to perform various functions including, but not limited to, controlling the industrial asset 100 by determining the fault probability 316 based, at least in part, on the plurality of frequency-parameter pairings 302 as described herein, as well as various other suitable computer-implemented functions.

FIGS. 3-8 depict various aspects of a system 300 for controlling the industrial asset 100 in the presence of a fault condition. It should be appreciated that the industrial asset 100 may be categorized as a member of an asset family. The asset family may include a plurality of similarly configured industrial assets. For example, the asset family may refer to a wind turbine model/platform, while the industrial asset 100 may be a particular installed wind turbine 114.

As depicted at 301, in an embodiment, the controller 200 may be configured to determine a plurality of frequency-parameter pairings 302. The plurality of frequency-parameter pairings 302 may correspond to at least one power spectral density 304 of the industrial asset 100. Each frequency-parameter pairing 306 may be indicative of an energy-level distribution for a parameter of the industrial asset 100 across a plurality of frequency intervals 308 of a portion of the power spectral density 304. The controller 200 may, in an embodiment, determine a deviation score 310 for each of the plurality of frequency-parameter pairings 302. Each of the deviation scores 310 may be indicative of a magnitude difference between the energy-level distribution of each frequency-parameter pairing 306 and a corresponding energy-level distribution of a nominal frequency-parameter pairing of the asset family. The corresponding energy-level distribution of the nominal frequency-parameter pairing may be represented by a corresponding power spectral density 312, for the asset family. Additionally, the controller 200 may be configured to determine a multi-variate anomaly score 314 based, at least in part, on the plurality of deviation scores 310. Further, the controller 200 may determine a fault probability 316 for the industrial asset 100 based, at least in part, on the multi-variate anomaly score 314. As depicted at 318, in an embodiment wherein the fault probability 316 exceeds a fault threshold 320, a control action 322 may be implemented.

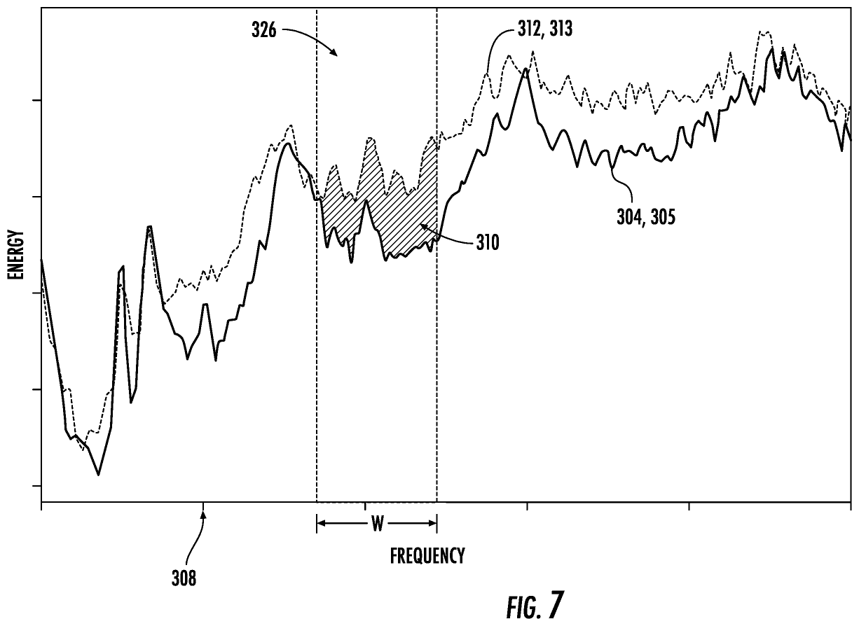

In an embodiment, the deviation scores 310 may, as depicted in FIG. 7, represent a distance between the energy-level distributions represented by the power spectral density 304 of the industrial asset 100 and the corresponding power spectral density 312 of the asset family. The deviation score 310 may be determined for each of the plurality of frequency-parameter pairings 302. In an embodiment, the deviation score 310 for any frequency-parameter pairing 306 may, for example, be an L2-distance, or similar measure, calculated for the frequency bands of the frequency-parameter pairing 306. The L2-distance may be calculated using known methods in the art. It should be appreciated that in an embodiment, the power spectral density 312 of the asset family may have a greater magnitude than the power spectral density 304 of the industrial asset 100 for a given frequency band. However, in an additional embodiment, the power spectral density 312 of the asset family may have a lesser magnitude than the power spectral density 304 of the industrial asset.

In order to determine the plurality of frequency-parameter pairings 302, the controller 200 may, in an embodiment, be configured to receive a plurality of time-series observations 324 from at least one sensor (e.g., the operational sensor(s) 158) of the industrial asset 100. The plurality of time-series observations 324 may correspond to a parameter (e.g., a monitored attribute) of the industrial asset 100. The plurality of time-series observations 324 may be recorded under a plurality of conditions affecting the industrial asset 100. For example, the plurality of time-series observations 324 may, in an embodiment, refer to a plurality of accelerations recorded by the operational sensor(s) 158 under a plurality of wind conditions (as monitored by the environmental sensor(s) 156) affecting the wind turbine 114.

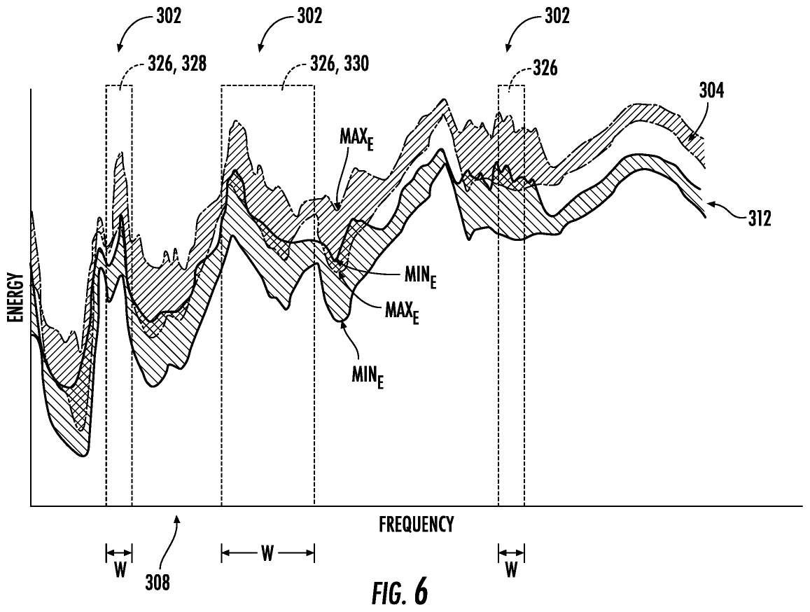

In an embodiment, the controller 200 may convert the plurality of time-series observations 324 into a corresponding power spectral density 304 of the industrial asset 100. In an additional embodiment, the controller 200 may be configured to receive the power spectral density 304. The power spectral density 304 may correspond to the energy levels of the parameter at the plurality of frequency intervals 308. Insofar as the plurality of time-series observations 324 may be recorded under the plurality of conditions affecting the industrial asset 100, the energy levels may correspond to a range of energy levels between a maximal energy level (MAX_{E}) and a minimal energy level (MINE) at each frequency of the power spectral density 304. In such an embodiment, the power spectral density 304 may, as depicted in FIG. 6, be defined by the range of energy levels.

It should be appreciated that, as depicted in FIG. 7, the power spectral densities 304, 312 may be transformed to facilitate the determination of the deviation score(s) 310. For example, the mean of the energy levels for the power spectral density 304 of the industrial asset 100 may be determined at each of the frequency intervals 308 to establish a mean power spectral density 305. The deviation score(s) 310 may represent a distance between the mean power spectral density 305 of the industrial asset 100 and a corresponding mean power spectral density 313 of the asset family.

It should be appreciated that, in an embodiment, indications of fault conditions may be detected in certain additional monitored parameters of the industrial asset 100. Accordingly, these additional parameters of interest may be indicated by additional pluralities of time series observations 324. The additional pluralities of time series observations 324 may similarly be converted into corresponding power spectral densities 304 such that each parameter of interest may be represented by a corresponding power spectral density 304. As such, the control of the industrial asset 100 via the systems and methods disclosed herein may be based on single monitored parameter or at least two monitored parameters.

In an embodiment, the controller 200 may be configured to identify at least one frequency band 326 of the plurality of frequency intervals 308. The frequency band(s) 326 may represent a portion of the frequency intervals 308 at which the power spectral density 304 of the industrial asset 100 deviates from the corresponding power spectral density 312 of the asset family.

The bandwidth (W) of the frequency band(s) 326 may, in an embodiment, be tailored in order to affect a detectability of the difference between the power spectral densities 304, 312. In other words, the controller 200 may, in an embodiment, determine a magnitude of the portion of the frequency intervals 308 at which a difference between the power spectral densities 304, 312 for a particular parameter may be detectable. The bandwidth (W) may correspond to the magnitude expressed in terms of hertz (Hz). For example, in an embodiment, the frequency band(s) 326 may have a bandwidth (W) of at least 0.1 Hz. In an additional embodiment, the frequency band(s) 326 may have a bandwidth (W) of less than or equal to 0.5 Hz. For example, the frequency band(s) 326 may have a bandwidth (W) of 0.3 Hz.

It should be appreciated that the controller 200 may, in an embodiment identify at least a first frequency band 328 and a second frequency band 330 for a power spectral density corresponding to a particular parameter. In such an embodiment, the power spectral density 304 may deviate from the power spectral density 312 for the asset family at each of the first and second frequency bands 328, 330. Additionally, in an embodiment, the plurality frequency bands 326 may have differing bandwidths (W) (e.g., bandwidth combinations) at different frequency intervals 308. For example, in an embodiment, the first frequency band 328 may extend between 0.9 and 1.2 Hz, while the second frequency band 330 may extend between 1.5 and 1.9 Hz.

It should further be appreciated that the controller 200 may, in an embodiment, determine the plurality of frequency bands 326 for each power spectral density 304. For example, in an embodiment, the parameter of the industrial asset 100 may be a first parameter of the industrial asset 100. As such, the power spectral density 304 may be a first power spectral density corresponding to the first parameter. Additionally, a second power spectral density may correspond to a second parameter. In such an embodiment, the controller 200 may identify at least a first frequency band of the first power spectral density at which the first power spectral density deviates from the corresponding power spectral density 312 for the asset family at the first frequency band. Additionally, the controller 200 may identify at least a second frequency band of the second power spectral density at which the second power spectral density deviates from the corresponding power spectral density 312 for the asset family at the second frequency band.

Each frequency band 326 for each parameter may correspond to a frequency-parameter pairing 306. For example, in an embodiment, the plurality of frequency-parameter pairings 302 may correspond to a plurality of identified frequency bands 326 for the power spectral density 304 corresponding to a single parameter. However, in an additional embodiment, the plurality of frequency-parameter pairings 302 may correspond to a plurality of identified frequency bands 326 corresponding to at least two power spectral densities 304 of at least two parameters. As such, each frequency-parameter pairing 306 may correspond to a combination of a single frequency band 326 having a particular bandwidth (W) for a single parameter. An exemplary frequency-parameter pairing 306 may correspond to a frequency band extending between 0.6 and 0.9 Hz for a power spectral density 304 corresponding to a vibration of the rotor shaft 122 of the wind turbine 114. By way of further illustration, in an embodiment, a frequency-parameter pairing 306 may correspond to a frequency band extending between 1.45 and 1.55 Hz for a power spectral density 304 corresponding to a rotational speed of a component of the industrial asset 100.

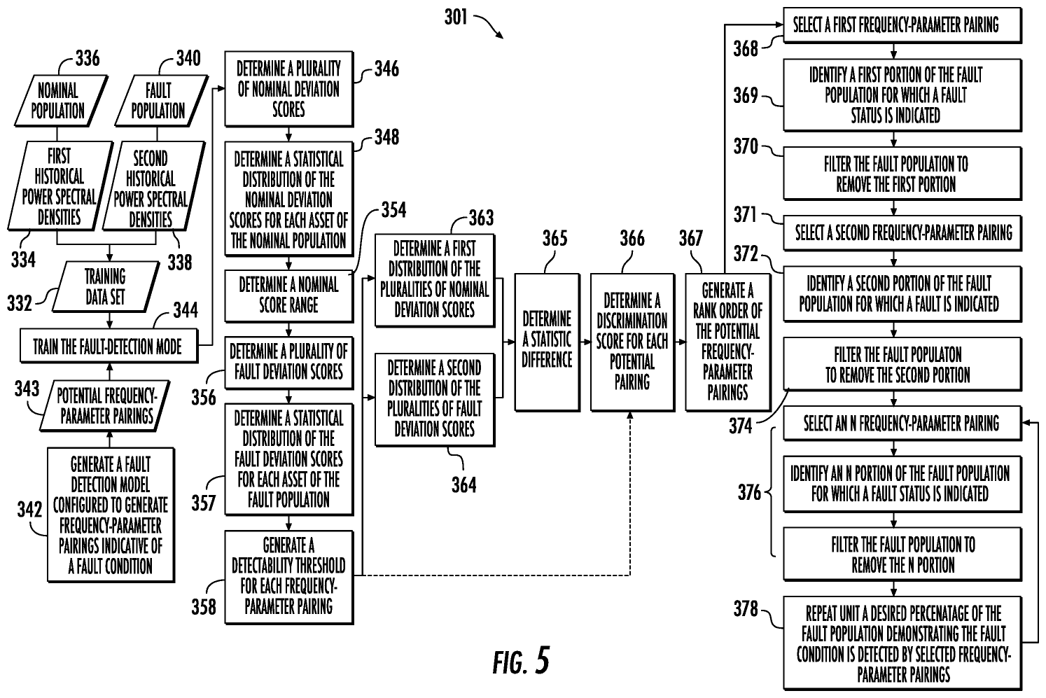

As depicted in FIG. 5, in an embodiment, to determine the plurality of frequency-parameter pairings 302 at step 301, the controller 200 may be configured to receive a training data set 332. The training data set 332 may, in an embodiment, include a first plurality of historical power spectral densities 334. The first plurality of historical power spectral densities 334 may correspond to a nominal population 336 of the asset family. In other words, the first plurality of historical power spectral densities 334 may be representative of a healthy portion (e.g., a portion operating in the absence of a fault condition) of the asset family. In an embodiment, the training data set 332 may also include a second plurality of historical power spectral densities 338. The second historical power spectral densities 338 may correspond to a fault population 340 of the asset family. It should be appreciated that the first plurality of historical power spectral densities 334 may be indicative of a nominal operating condition for a plurality of parameters. Additionally, the second plurality of historical power spectral densities 338 may be indicative of at least one fault condition for the plurality of parameters.

It should also be appreciated that the training data set 332 may include historical observations of the operations of the plurality of the industrial assets of the asset family. In an embodiment, the training data set may also include an engineering diagnostic expert system. The engineering diagnostic expert system may include manifestations of the engineering domain knowledge, such as troubleshooting guides, anomaly validation reports, after-action reports, design specifications, testing reports, and/or other captures of the experience and decision-making knowledge of a human expert. As such, the training data set 332 may include data indicative of both nominal operating states of industrial assets of the asset family and operating states reflecting an impact of a fault on the operations of industrial assets of the asset family.

In an embodiment, the controller 200 of the system 300 may generate a fault-detection model 342. The fault-detection model 342 may be configured to implement the methods disclosed herein to generate the frequency-parameter pairings 306 which may be indicative of a fault condition. In other words, the fault-detection model 342 may be configured to determine the plurality of frequency-parameter pairings 302 which are indicative of the at least one fault condition. In an embodiment, the plurality of frequency-parameter pairings 302 may be determined from a plurality of potential frequency-parameter pairings 343 for the first and second pluralities of historical power spectral densities 334, 338. It should be appreciated that for any given industrial asset, a substantial quantity of potential frequency-parameter pairings 343 may be available, but that relatively few of the potential frequency-parameter pairings 343 may be indicative of a fault condition. As such, it may be desirable to identify those frequency-parameter pairings which may be indicative of the fault in order to assess the operating state (e.g., fault or nominal) of the industrial asset 100 and implement a control action 322 when a fault is indicated.

In an embodiment, the fault-detection model 342 may include a statistical algorithm and/or a machine learning algorithm. In such embodiments, the statistical/machine learning algorithm may be configured to identify the frequency-parameter pairing(s) 306 which may be indicative of a fault condition of the industrial asset 100 by identifying an optimal transfer function between the power spectral densities 304 of the industrial asset 100 and the corresponding power spectral densities 312 of the asset family.

As depicted at 344, in an embodiment, the controller 200 may be configured to train (e.g., via machine learning) the fault-detection model 342. The training of the fault-detection model 342 may be accomplished via the training data set 332. The training of the fault-detection model 342 may facilitate the determination/identification of the plurality of frequency-parameter pairings 302 which may be indicative of the at least one fault condition.

In an embodiment, training the fault-detection model 342 may include developing a plurality of correlations between the first plurality of historical power spectral densities 334 and the second plurality of historical power spectral densities 338. For example, in an embodiment, the controller 200 may include a supervised machine learning algorithm which may apply what has been learned in the past to new data to identify frequency-parameter pairings 306 indicative of a fault condition. Starting from the model built, the learning algorithm may produce an inferred function to make a determination about the output values. As such, the controller 200 may be able to provide targets for any new input after sufficient training. The learning algorithm may also compare its output with the correct, intended output to find errors in order to modify the model accordingly. Thus, as shown at 344, the training of the fault-detection model 342 may facilitate the determination of the particular frequency-parameter pairings 306 which may be required to detect a desired percentage of the fault population 340.

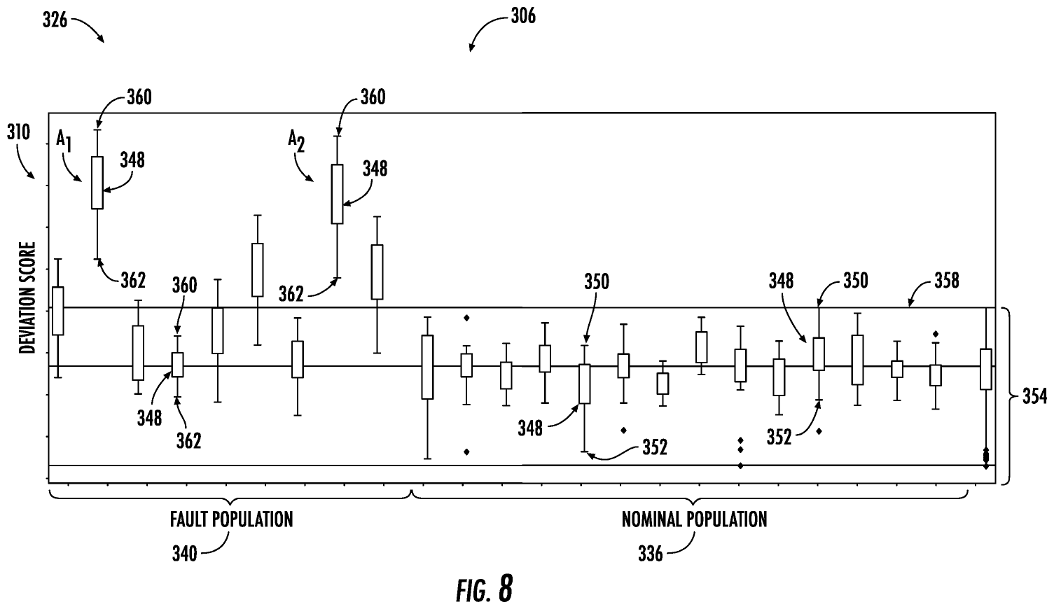

As depicted in FIG. 8, wherein a box plot representation of a plurality of statistical distributions of deviation scores 310 (e.g., a distribution of L-2 distances) for industrial assets of the asset family is illustrated for a frequency-parameter pairing 306, the correlations between the first and second pluralities of power spectral densities 334, 338 may be determined for each of the potential frequency-parameter pairings 343. The correlation may be an indication of a degree of discrimination achieved/achievable by each potential frequency-parameter pairing 343. In other words, the correlation may indicate whether for any particular potential frequency-parameter pairing 343 differences between the power spectral density of the industrial asset 100 and that of the asset family may be attributed to a fault condition or whether they may be attributed to variations in the nominal operating state. For example, the correlation may indicate whether for any particular potential frequency-parameter pairing 343, the potential fault signals may be discernible amongst the noise present in the first plurality of historical power spectral densities 334.

Accordingly, in an embodiment, the controller 200 may be configured to determine a plurality of nominal deviation scores 346. The plurality of nominal deviation scores 346 may be determined for the historical power spectral density of each industrial asset of the nominal population 336 relative to the historical power spectral densities of each other industrial asset of the nominal population 336. The nominal deviation scores 346 may, therefore, be indicative of variations in the power spectral densities of the known nominal population 336. In other words, the power spectral density of each known healthy industrial asset of the asset family may be compared to the power spectral density of every other known healthy industrial asset of the asset family in order to identify deviations between the power spectral densities which may be attributable to variations in nominal operations. It should be appreciated that the nominal deviation scores may be determined for each of the potential frequency-parameter pairings 343.

The controller 200 may, in an embodiment, be configured to determine a statistical distribution 348 of the plurality of nominal deviation scores 346 for each industrial asset of the nominal population 336. The statistical distribution 348 may extend between a maximal nominal deviation score 350 and a minimal nominal deviation score 352 for each industrial asset of the nominal population 336 for each of the potential frequency-parameter pairings 343. For example, the statistical distribution 348 may be represented by a box plot or other similar representation, such as depicted in FIG. 8.

In an embodiment, the controller 200 may determine a nominal score range 354 for the first plurality of historical power spectral densities 334. The nominal score range 354 may extend between the maximal nominal deviation score 350 and the minimal nominal deviation score 352 of the first plurality of historical power spectral densities 334. As such, the nominal score range 354 may correspond to a nominal operating range of the nominal population 336 of the asset family at the single frequency band 326 of the frequency-parameter pairing 306.

As is further depicted in FIG. 8, the controller 200 may, in an embodiment, determine a plurality of fault deviation scores 356. The plurality of fault deviation scores 356 may be determined for the historical power spectral density of each industrial asset of the fault population 340 relative to the first plurality of historical power spectral densities 334. The fault deviation scores 356 may, therefore, be indicative of a difference between the power spectral density of the faulty industrial asset of the fault population 340 and the power spectral densities of each of the healthy industrial assets of the nominal population 336. In such an embodiment, the power spectral density of each member of the fault population 340 may be compared to the power spectral density of each member of the nominal population 336. It should be appreciated that each fault deviation score of the plurality of fault deviation scores 356 may be determined for each of the potential frequency-parameter pairings 343.

As depicted at 357, the controller 200 may, in an embodiment, be configured to determine the statistical distribution 348 of the plurality of fault deviation scores 356 for each industrial asset of the fault population 340. The statistical distribution 348 may extend between a maximal fault deviation score 360 and a minimal fault deviation score 362 for each industrial asset of the fault population 340 for each of the potential frequency-parameter pairings 343. For example, the statistical distribution 348 may be represented by a box plot or other similar representation, such as depicted in FIG. 8.

In an embodiment, the controller 200 may be configured to generate a detectability threshold 358. The detectability threshold 358 may be generated for each of the plurality of frequency-parameter pairings 302. The detectability threshold 358 may be based, at least in part, on the maximal nominal deviation score 350 of at least one power spectral density of the first plurality of historical power spectral densities 334 (e.g. of the nominal population 336). The detectability threshold 358 may, in an embodiment, correspond to a magnitude above which a deviation score 310 may be indicative of a fault condition. For example, in an embodiment such as depicted in FIG. 8, industrial assets A₁ and A₂ of the fault population 340 are depicted as having minimal fault deviation scores 362 which are greater than the detectability threshold 358. In such an embodiment, industrial assets A₁ and A₂ may be indicated as faulty for the particular frequency-parameter pairing 306 represented by FIG. 8.

In an additional embodiment, the controller 200 may be configured to determine a first distribution 363 of the pluralities of nominal deviation scores 346 for each of the potential frequency-parameter pairings 343. The first distribution 363 may include an aggregation of substantially all of the nominal deviation scores 346 corresponding to the entirety of the nominal population 336 for a single potential frequency-parameter pairing 343. Additionally, the controller 200 may be configured to determine a second distribution 364 of the pluralities of fault deviation scores 356 for each of the potential frequency-parameter pairings 343 of the fault population 340 relative to the nominal population 336. The second distribution 364 may include an aggregation of substantially all of the fault deviation scores 356 corresponding to the entirety of the fault population 340 for the same single potential frequency-parameter pairing 343.

It should be appreciated that a distribution of the nominal deviation scores 346 (e.g., the first distribution 363) of the nominal population 336 for a single potential frequency-parameter pairing 343 may be different than a distribution of the fault deviation scores 356 (e.g., the second distribution 364) of the fault population 336 for the same potential frequency-parameter pairing 343. The degree of difference between the first and second distributions 363, 364 may be indicative of a degree of discrimination between the fault population 340 and the nominal population 336 for the potential frequency-parameter pairing 343. As such, the controller 200 may, in an embodiment, be configured to determine a statistical difference 365 between the first and second distributions 363, 364. For example, a statistical test of significance for comparing distributions may be employed to quantify the difference between the first and second distributions 363, 364.

In an exemplary embodiment a Kolmogorov-Smirnov test (KS-test), or other similar test, may be employed to determine the statistical difference 365 between the first and second distributions 363, 364. The KS-test may determine the supremum (e.g., maximal) difference between two empirical distributions (e.g. the first and second distributions 363, 364). As such, a relatively high Kolmogorov-Smirnov score (KS-score) may indicate a relatively high degree of discrimination between the first and second distributions 363, 364. Further, as between any pair of potential frequency-parameter pairings 343, the potential frequency-parameter pairing 343 having the higher KS-score may be deemed to be more discriminative of a portion of the fault population 340 than the potential frequency-parameter pairing 343 having the lower KS-score. As such, in an embodiment, a P-value may be calculated to determine the statistical significance of the KS-score. In such an embodiment, a P-value of at least 0.05 may be deemed to be statistically significant.

In an embodiment, the controller 200 may utilize the statistical difference 365 between the first distribution 363 of the plurality of nominal deviation scores 346 and the second distribution 364 of the plurality of fault deviation scores 356 to determine a discrimination score 366 for each of the plurality of potential frequency-parameter pairings 343. The discrimination score 366 may be indicative of the degree of discrimination between the nominal and fault populations 336, 340 of the asset family at the corresponding frequency-parameter pairing 306 in the presence of a fault condition. As such, the discrimination score 366 may be indicative of a degree of usefulness of a deviation score 310 for the frequency-parameter pairing 306 in the determination of the fault probability 318.

In an embodiment, the discrimination score 366 may be employed to determine which of the potential frequency-parameter pairings 343 may be of value in determining whether the industrial asset 100 is operating in the presence of a fault condition. As such, the controller 200 may, in an embodiment, generate a rank ordering 367 of the plurality of potential frequency-parameter pairings 343 for a fault condition. The rank ordering 367 may be based, at least in part, on the discrimination score 366. The rank ordering 367 may, for example, be arranged in descending order from the frequency-parameter pairing 306 having the highest discrimination score 366 relative to the remainder of the plurality of potential frequency-parameter pairings 343. It should be appreciated that the rank ordering 367 may vary depending on the particular fault condition to be detected.

In order to determine the frequency-parameter pairings 306 of the plurality of frequency-parameter pairings 302 which are indicative of the fault condition, the controller 200 may identify which frequency-parameter pairing(s) 306 of the plurality of potential frequency-parameter pairings 343 is indicative of the fault condition in question. As such, in an embodiment, the controller 200 may select a first frequency-parameter pairing 368 of the plurality of potential frequency-parameter pairings 343. The selection of the first frequency-parameter pairing 368 may be based, at least in part, on the rank ordering 367 for the fault condition. The controller 200 may then identify a first portion 369 of the fault population 340 for which the first frequency-parameter pairing 368 may be indicative of a fault status. As depicted at 370, in an embodiment, the controller 200 may filter the first portion 369 of the fault population 340 so as to remove the first portion 369 of the fault population 340 from further consideration during the identification of the frequency-parameter pairings 306 constituting the plurality of frequency-parameter pairings 302.

In an embodiment, the controller 200 may identify additional frequency-parameter pairings 306 which are indicative of the fault condition by selecting a second frequency-parameter pairing 371 of the remaining potential frequency-parameter pairings 343. The selection of the second frequency-parameter pairing 371 may be based, at least in part, on the rank ordering 367 for the fault condition. For example, in an embodiment, the second frequency-parameter pairing 371 may have a discrimination score 366 which is less than the discrimination score 366 of the first frequency-parameter pairing 368 but is greater than or equal to any remaining frequency-parameter pairing 306 of the plurality of potential frequency-parameter pairings 343.

In an embodiment, the controller 200 may identify a second portion 372 of the fault population 340 for which the second frequency-parameter pairing 371 may be indicative of a fault status. As depicted at 374, in an embodiment, the controller 200 may filter the second portion 372 of the fault population 340 so as to remove the second portion 372 of the fault population 340 from further consideration during the identification of the frequency-parameter pairings 306 constituting the plurality of the frequency-parameter pairings 302.

As depicted at 376, the selection, identification, and filtering of additional frequency-parameter pairings and corresponding fault populations may be repeated to identify additional frequency-parameter pairings 306 (e.g., n frequency-parameter pairings) forming the plurality of frequency-parameter pairings 302. In an embodiment, as indicated at 378, the selection, identification, and filtering steps depicted at 376 may be repeated until a desired percentage of the fault population 340 demonstrating the fault condition is detected by the selected frequency-parameter pairings 306. For example, in an embodiment, it may be desirable to continue the selection, identification, and filtering of the plurality of potential frequency-parameter pairings 343 until the entirety of the fault population 340 is identified by the plurality of frequency-parameter pairings 302. However, in an additional embodiment, the selection, identification, and filtering of the plurality of potential frequency-parameter pairing 343 may be halted upon the identification of at least 75% of the fault population 340. It should be appreciated that the magnitude of the desired percentage may correspond to a given use case for the system 300. It should be further appreciated that for certain fault conditions, the desired identification percentage may be achieved by the selection of the first frequency-parameter pairing 368 of the plurality of potential frequency-parameter pairings 343 and may, therefore not require the identification of additional frequency-parameter pairings 306.

In an embodiment, the plurality of potential frequency-parameter pairings 343 may have a plurality of bandwidth (W) combinations for each parameter of the plurality of parameters. Accordingly, generating the rank ordering 367 may include determining, via the controller 200, the discrimination score 366 for each of the plurality of bandwidth (W) combinations for each parameter. For example, in an embodiment, for a given parameter, a bandwidth (W) extending between 0.6 and 1.2 Hz may have a different discrimination score 366 than a bandwidth (W) extending between 0.7 and 1.0 Hz.

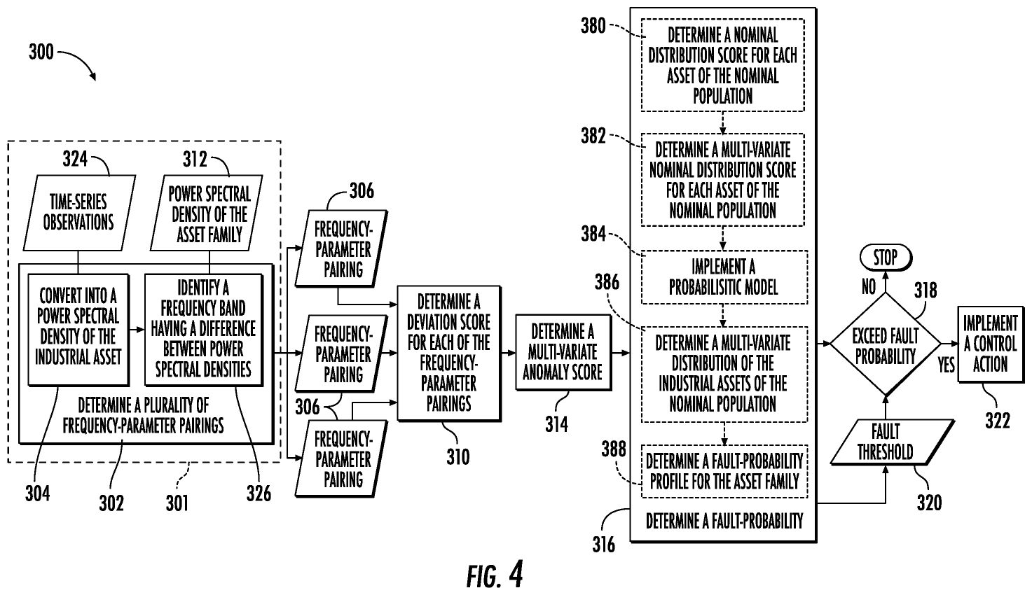

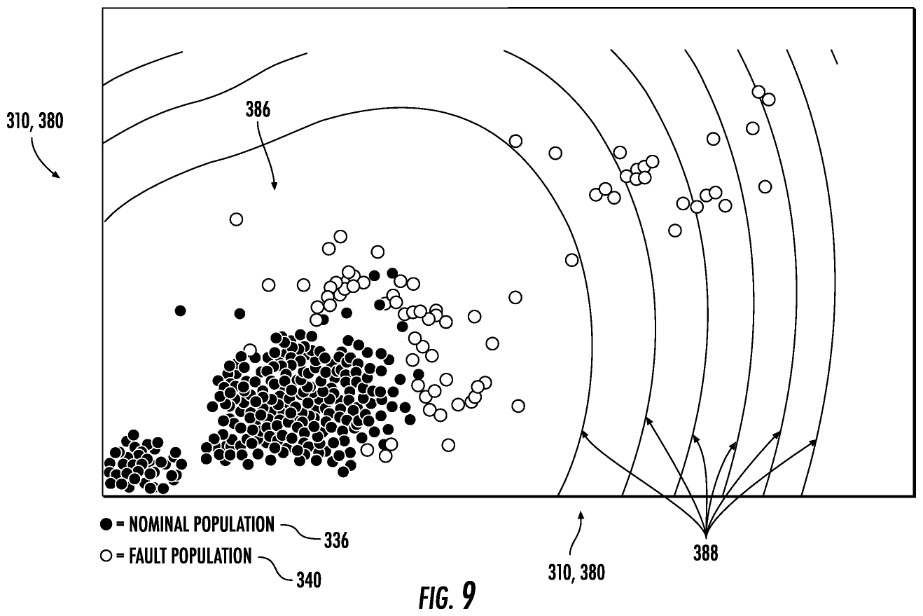

Referring again to FIG. 4 and also to FIG. 9 in particular, in order to determine the fault probability 316 for the industrial asset 100, the controller 200 may, in an embodiment, determine a nominal distribution score 380 for each industrial asset of the nominal population 336. The nominal distribution score 380 may be determined for each of the plurality of frequency-parameter pairings 302. In an embodiment, the plurality of frequency-parameter pairings 302 may include such frequency-parameter pairings 306 as may facilitate the detection of the desired portion of the fault population 340. In an embodiment, the nominal distribution score 380 may be indicative of a distribution of the nominal deviation scores 346 for each industrial asset of the nominal population 336 within the nominal score range 354. The nominal distribution score 380 may, for example, be indicative of a distance of a mean of the nominal deviation scores 346 from a mean of the nominal score range 354.

In an embodiment, the controller 200 may be configured to determine a multi-variate nominal distribution score 382 for each industrial asset of the nominal population 336. The multi-variate nominal distribution score 382 may be based, at least in part, on the nominal distribution score 380 for each of the plurality of frequency-parameter pairings. For example, the multi-variate nominal distribution score 382 may be determined by combining each of the nominal distribution scores 380 into a coordinate having a number of dimensions corresponding to the number of frequency-parameter pairings 306 of the plurality of frequency-parameter pairings 302.

In an embodiment, the controller 200 may implement a probabilistic model 384 to determine a multi-variate distribution 386 of the industrial assets of the nominal population 336. The multi-variate distribution 386 may be based on the corresponding multi-variate nominal distribution scores 380. For example, in an embodiment, a Gaussian Mixture Model may be employed to model the distribution of the nominal population 336.

Based on the probabilistic model 384, the controller 200 may, in an embodiment, determine a fault-probability profile 388 for the asset family. The fault-probability profile 388 may indicate the likelihood that the deviation scores 310 for the industrial asset 100 for each of the plurality of frequency-parameter pairings 302 are indicative of a fault condition. The dimensionality of the fault-probability profile 388 may correspond to the number of frequency-parameter pairings 306 of the plurality of frequency-parameter pairings 302. For example, in an embodiment, the plurality of frequency-parameter pairings 302 may include at least three frequency-parameter pairings 306. In such an embodiment, the fault-probability profile 388 may be a three-dimensional fault probability profile 388. It should be appreciated that increasing the number of frequency-parameter pairings 306 may increase the granularity of the system 300.

In an embodiment, determining the fault probability 316 may be facilitated by the establishment of the fault threshold 320. In such an embodiment, the fault threshold 320 may increase the detectability of a fault condition. For example, the fault threshold may be established via the fitting of a receiver-operating-characteristic curve (ROC-curve). As such, the controller 200 may, in an embodiment, fit the ROC-curve to a distribution of the industrial assets of the fault population 340 and the nominal population 336.

Furthermore, the skilled artisan will recognize the interchangeability of various features from different embodiments. Similarly, the various method steps and features described, as well as other known equivalents for each such methods and feature, can be mixed and matched by one of ordinary skill in this art to construct additional systems and techniques in accordance with principles of this disclosure. Of course, it is to be understood that not necessarily all such objects or advantages described above may be achieved in accordance with any particular embodiment. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

Further aspects of the invention are provided by the subject matter of the following clauses:

Clause 1. A method for controlling an industrial asset of an asset family, wherein the asset family comprises a plurality of industrial assets, the method comprising: determining, via a controller, a plurality of frequency-parameter pairings corresponding to at least one power spectral density of the industrial asset, each frequency-parameter pairing comprising an energy-level distribution for a parameter of the industrial asset across a plurality of frequency intervals of a portion of the at least one power spectral density: determining, via the controller, a deviation score for each of the plurality of frequency-parameter pairings, wherein each of the deviation scores is indicative of a magnitude difference between the energy-level distribution of each frequency-parameter pairing and a corresponding energy-level distribution of a nominal frequency-parameter pairing of the asset family: determining, via the controller, a multi-variate anomaly score based, at least in part, on the deviation scores: determining, via the controller, a fault probability for the industrial asset based, at least in part, on the multi-variate anomaly score; and implementing a control action based on the fault probability exceeding a fault threshold.

Clause 2. The method of clause 1, wherein determining the plurality of frequency-parameter pairings further comprises: receiving, via the controller, a plurality of time-series observations from at least one sensor of the industrial asset, the plurality of time-series observations corresponding to a parameter of the industrial asset: converting, via the controller, the plurality of time-series observations into the least one power spectral density of the industrial asset; and identifying, via the controller, at least one frequency band of the plurality of frequency intervals at which the power spectral density of the industrial asset deviates from the corresponding power spectral density for the asset family at the at least one frequency band.

Clause 3. The method of any preceding clause, wherein the at least one power spectral density comprises a range of energy levels at each of the plurality of frequency intervals of the at least one power spectral density, the range of energy levels being defined between a maximal energy level and a minimal energy level of the parameter at each frequency interval and being indicative of an energy level of the parameter at each frequency interval for a plurality of operating conditions of the industrial asset.

Clause 4. The method of any preceding clause, wherein the identifying at least one frequency band further comprises: identifying, via the controller, a first frequency band of the power spectral density corresponding to the parameter at which the power spectral density of the industrial asset deviates from the corresponding power spectral density for the asset family at the first frequency band; and identifying, via the controller, a second frequency band of the power spectral density corresponding to the parameter at which the power spectral density of the industrial asset deviates from the corresponding power spectral density for the asset family at the second frequency band.

Clause 5. The method of any preceding clause, wherein the parameter of the industrial asset is a first parameter of the industrial asset, wherein the at least one power spectral density comprises a first power spectral density corresponding to the first parameter and a second power spectral density corresponding to a second parameter of the industrial asset, and wherein identifying at least one frequency band further comprises: identifying, via the controller, a first frequency band of the first power spectral density at which the first power spectral density deviates from the corresponding power spectral density for the asset family at the first frequency band; and identifying, via the controller, a second frequency band of the second power spectral density at which the second power spectral density deviates from the corresponding power spectral density for the asset family at the second frequency band.

Clause 6. The method of any preceding clause, wherein determining the plurality of frequency-parameter pairings further comprises: receiving, via the controller, a training data set comprising a first plurality of historical power spectral densities corresponding to a nominal population of industrial asset of the asset family and a second plurality of historical power spectral densities corresponding to a fault population of the asset family, wherein the first plurality of historical power spectral densities is indicative of a nominal operating condition for a plurality of parameters, and wherein the second plurality of historical power spectral densities is indicative of at least one fault condition for the plurality of parameters: generating, via the controller, a fault-detection model configured to determine the plurality of frequency-parameter pairings which are indicative of the at least one fault condition, the plurality of frequency-parameter pairings being determined from a plurality of potential frequency-parameter pairings for the first and second pluralities of historical power spectral densities; and training, via the controller, the fault-detection model via the training data set so as to determine the plurality of frequency-parameter pairings indicative of the at least one fault condition.

Clause 7. The method of any preceding clause, wherein determining the plurality of frequency-parameter pairings which are indicative of the at least one fault condition further comprises: determining, via the controller, a plurality of nominal deviation scores for each historical power spectral density of the first plurality of historical power spectral densities of each industrial asset of the nominal population relative to each other historical power spectral density of the of the first plurality of historical power spectral densities of each other industrial asset of the nominal population, wherein the plurality of nominal deviation scores is determined for each of the potential frequency-parameter pairings: determining, via the controller, a statistical distribution of the plurality of nominal deviation scores for each industrial asset of the nominal population, the statistical distribution extending between a maximal nominal deviation score and a minimal nominal deviation score for each industrial asset of the nominal population for each of the potential frequency-parameter pairings, determining, via the controller, a nominal score range extending between the maximal nominal deviation score and the minimal nominal deviation score of the first plurality of historical power spectral densities, wherein the nominal score range corresponds to a nominal operating state of the nominal population of the asset family at the at least one frequency band: determining, via the controller, a plurality of fault deviation scores for each historical power spectral density of the second plurality of historical power spectral densities of each industrial asset of the fault population relative to the first plurality of historical power spectral densities, wherein the plurality of fault deviation scores is determined for each of the potential frequency-parameter pairings: determining, via the controller, the statistical distribution of the plurality of fault deviation scores for each industrial asset of the fault population, the statistical distribution extending between a maximal fault deviation score and a minimal fault deviation score for each industrial asset of the fault population for each of the potential frequency-parameter for pairings; and generating, via the controller, a detectability threshold for each of the plurality of frequency-parameter pairings based on the maximal nominal deviation score of at least one power spectral density of the nominal population.

Clause 8. The method of any preceding clause, wherein determining the plurality of frequency-parameter pairings which are indicative of the at least one fault condition further comprises: determining, via the controller, a first distribution of the pluralities of nominal deviation scores for each of the potential frequency-parameter for pairings: determining, via the controller, a second distribution of the pluralities of fault deviation scores for each of the potential frequency-parameter for pairings; and determining, via the controller, a discrimination score for each of the plurality of potential frequency-parameter pairings based on a statistical difference between the first distribution and the second distribution, the discrimination score being indicative of a degree of discrimination between the nominal and fault populations of the asset family at the corresponding frequency-parameter pairing in the presence of the at least one fault condition.

Clause 9. The method of any preceding clause, wherein determining the plurality of frequency-parameter pairings which are indicative of the at least one fault condition further comprises: generating, via the controller, a rank ordering of the plurality of potential frequency-parameter pairings for the at least one fault condition based, at least in part, on the discrimination score.

Clause 10. The method of any preceding clause, wherein determining the plurality of frequency-parameter pairings which are indicative of the at least one fault condition further comprises: a) selecting, via the controller, a first frequency-parameter pairing of the plurality of potential frequency-parameter pairings based, at least in part, on the rank ordering for the at least one fault condition: b) identifying, via the controller, a first portion of the fault population for which the first frequency-parameter pairing is indicative of a fault status: c) filtering, via the controller, the first portion of the fault population so as to remove the first portion from the fault population: d) selecting, via the controller, a second frequency-parameter pairing of the plurality of potential frequency-parameter pairings based, at least in part, on the rank ordering for the at least one fault condition: e) identifying, via the controller, a second portion of the fault population for which the second frequency-parameter pairing is indicative of a fault status: f) filtering, via the controller, the second portion of the fault population so as to remove the second portion from the fault population; and g) repeating steps a)-f) until a desired percentage of the fault population demonstrating the at least one fault condition is detected by selected frequency-parameter pairings.

Clause 11. The method of any preceding clause, wherein the plurality of potential frequency-parameter pairings have a plurality of bandwidth combinations for each parameter of the plurality of parameters, and wherein generating the rank ordering further comprises: determining, via the controller, the discrimination score for each of the plurality of bandwidth combinations for each parameter.

Clause 12. The method of any preceding clause, wherein determining the fault probability for the industrial asset further comprises: determining, via the controller, a nominal distribution score for each industrial asset of the nominal population for each of the plurality of frequency-parameter pairings, the nominal distribution score being indicative of a distribution of the nominal deviation scores for each industrial asset of the nominal population within the nominal score range for each of the plurality of frequency-parameter pairings: determining, via the controller, a multi-variate nominal distribution score for each industrial asset of the nominal population based, at least in part, on the nominal distribution score for each of the plurality of frequency-parameter pairings: implementing, via the controller, a probabilistic model to determine a multi-variate distribution of the industrial assets of the nominal population based on the corresponding multi-variate nominal distribution scores; and determining, via the controller, a fault-probability profile for the asset family based on the probabilistic model.

Clause 13. The method of any preceding clause, further comprising: establishing the fault threshold via a fitting of a receiver-operating-characteristic curve (ROC-curve) to a distribution of the industrial assets of the fault population relative to the industrial assets of the nominal population.

Clause 14. The method of any preceding clause, wherein the plurality of frequency-parameter pairings comprises at least three frequency-parameter pairings, and wherein the fault-probability profile comprises at least a three-dimensional fault-probability profile.

Clause 15. The method of any preceding clause, wherein the industrial asset comprises a wind turbine.

Clause 16. A system for controlling an industrial asset of an asset family, wherein the asset family comprises a plurality of industrial assets, the system comprising: at least one sensor operably coupled to the industrial asset; and a controller communicatively coupled to the at least one sensor, the controller comprising at least one processor configured to perform a plurality of operations, the plurality of operations comprising: determining a plurality of frequency-parameter pairings corresponding to at least one power spectral density of the industrial asset, each frequency-parameter pairing comprising an energy-level distribution for a parameter of the industrial asset across a plurality of frequency intervals of a portion of the at least one power spectral density, determining a deviation score for each of the plurality of frequency-parameter pairings, wherein each of the deviation scores is indicative of a magnitude difference between the energy-level distribution of each frequency-parameter pairing and a corresponding energy-level distribution of a nominal frequency-parameter pairing of the asset family, determining a multi-variate anomaly score based, at least in part, on the deviation scores, determining a fault probability for the industrial asset based, at least in part, on the multi-variate anomaly score, and implementing a control action based on the fault probability exceeding a fault threshold.

Clause 17. The system of any preceding clause, wherein determining the plurality of frequency-parameter pairings further comprises: receiving a plurality of time-series observations from the at least one sensor, the plurality of time-series observations corresponding to a parameter of the industrial asset: converting the plurality of time-series observations into the least one power spectral density of the industrial asset, wherein the at least one power spectral density comprises a range of energy levels at each of the plurality of frequency intervals of the at least one power spectral density, the range of energy levels being defined between a maximal energy level and a minimal energy level of the parameter at each frequency interval and being indicative of an energy level of the parameter at each frequency interval for a plurality of operating conditions of the industrial asset; and identifying at least one frequency band of the plurality of frequency intervals at which the power spectral density of the industrial asset deviates from the corresponding power spectral density for the asset family at the at least one frequency band.

Clause 18. The system of any preceding clause, wherein determining the plurality of frequency-parameter pairings further comprises: receiving a training data set comprising a first plurality of historical power spectral densities corresponding to a nominal population of the asset family and a second plurality of historical power spectral densities corresponding to a fault population of the asset family, wherein the first plurality of historical power spectral densities is indicative of a nominal operating condition for a plurality of parameters, and wherein the second plurality of historical power spectral densities is indicative of at least one fault condition for the plurality of parameters: generating a fault-detection model configured to determine the plurality of frequency-parameter pairings which are indicative of the at least one fault condition, the plurality of frequency-parameter pairings being determined from a plurality of potential frequency-parameter pairings for the first and second pluralities of historical power spectral densities; and training the fault-detection model via the training data set so as to determine the plurality of frequency-parameter pairings indicative of the at least one fault condition.

Clause 19. The system of any preceding clause, wherein determining the fault probability for the industrial asset further comprises: determining a nominal distribution score for each industrial asset of the nominal population for each of the plurality of frequency-parameter pairings, the nominal distribution score being indicative of a distribution of the nominal deviation scores for each industrial asset of the nominal population within the nominal score range for each of the plurality of frequency-parameter pairings: determining a multi-variate nominal distribution score for each industrial asset of the nominal population based, at least in part, on the nominal distribution score for each of the plurality of frequency-parameter pairings: implementing a probabilistic model to determine a multi-variate distribution of the industrial assets of the nominal population based on the corresponding multi-variate nominal distribution scores; and determining a fault-probability profile for the asset family based on the probabilistic model.

Clause 20. The system of any preceding clause, further comprising: fitting a receiver-operating-characteristic curve (ROC-curve) to a mean distance of a distribution of the industrial assets of the fault population relative to the multi-variate distribution of the industrial assets of the nominal population as indicated by the fault-probability profile for the asset family, wherein the ROC-curve corresponds to the fault threshold.

What is claimed is:

1. A method for controlling an industrial asset of an asset family, wherein the asset family comprises a plurality of industrial assets, the method comprising:
determining, via a controller, a plurality of frequency-parameter pairings corresponding to at least one power spectral density of the industrial asset, each frequency-parameter pairing comprising an energy-level distribution for a parameter of the industrial asset across a plurality of frequency intervals of a portion of the at least one power spectral density;
determining, via the controller, a deviation score for each of the plurality of frequency-parameter pairings, wherein each of the deviation scores is indicative of a magnitude difference between the energy-level distribution of each frequency-parameter pairing and a corresponding energy-level distribution of a nominal frequency-parameter pairing of the asset family;
determining, via the controller, a multi-variate anomaly score based, at least in part, on the deviation scores;
determining, via the controller, a fault probability for the industrial asset based, at least in part, on the multi-variate anomaly score; and
implementing a control action based on the fault probability exceeding a fault threshold.

2. The method of claim 1, wherein determining the plurality of frequency-parameter pairings further comprises:
receiving, via the controller, a plurality of time-series observations from at least one sensor of the industrial asset, the plurality of time-series observations corresponding to a parameter of the industrial asset;
converting, via the controller, the plurality of time-series observations into the least one power spectral density of the industrial asset; and
identifying, via the controller, at least one frequency band of the plurality of frequency intervals at which the power spectral density of the industrial asset deviates from the corresponding power spectral density for the asset family at the at least one frequency band.

3. The method of claim 2, wherein the at least one power spectral density comprises a range of energy levels at each of the plurality of frequency intervals of the at least one power spectral density, the range of energy levels being defined between a maximal energy level and a minimal energy level of the parameter at each frequency interval and being indicative of an energy level of the parameter at each frequency interval for a plurality of operating conditions of the industrial asset.

4. The method of claim 2, wherein the identifying at least one frequency band further comprises:
identifying, via the controller, a first frequency band of the power spectral density corresponding to the parameter at which the power spectral density of the industrial asset deviates from the corresponding power spectral density for the asset family at the first frequency band; and
identifying, via the controller, a second frequency band of the power spectral density corresponding to the parameter at which the power spectral density of the industrial asset deviates from the corresponding power spectral density for the asset family at the second frequency band.

5. The method of claim 2, wherein the parameter of the industrial asset is a first parameter of the industrial asset, wherein the at least one power spectral density comprises a first power spectral density corresponding to the first parameter and a second power spectral density corresponding to a second parameter of the industrial asset, and wherein identifying at least one frequency band further comprises:
identifying, via the controller, a first frequency band of the first power spectral density at which the first power spectral density deviates from the corresponding power spectral density for the asset family at the first frequency band; and
identifying, via the controller, a second frequency band of the second power spectral density at which the second power spectral density deviates from the corresponding power spectral density for the asset family at the second frequency band.

6. The method of claim 2, wherein determining the plurality of frequency-parameter pairings further comprises:
receiving, via the controller, a training data set comprising a first plurality of historical power spectral densities corresponding to a nominal population of industrial asset of the asset family and a second plurality of historical power spectral densities corresponding to a fault population of the asset family, wherein the first plurality of historical power spectral densities is indicative of a nominal operating condition for a plurality of parameters, and wherein the second plurality of historical power spectral densities is indicative of at least one fault condition for the plurality of parameters;
generating, via the controller, a fault-detection model configured to determine the plurality of frequency-parameter pairings which are indicative of the at least one fault condition, the plurality of frequency-parameter pairings being determined from a plurality of potential frequency-parameter pairings for the first and second pluralities of historical power spectral densities; and
training, via the controller, the fault-detection model via the training data set so as to determine the plurality of frequency-parameter pairings indicative of the at least one fault condition.

7. The method of claim 6, wherein determining the plurality of frequency-parameter pairings which are indicative of the at least one fault condition further comprises:
determining, via the controller, a plurality of nominal deviation scores for each historical power spectral density of the first plurality of historical power spectral densities of each industrial asset of the nominal population relative to each other historical power spectral density of the of the first plurality of historical power spectral densities of each other industrial asset of the nominal population, wherein the plurality of nominal deviation scores is determined for each of the potential frequency-parameter pairings;
determining, via the controller, a statistical distribution of the plurality of nominal deviation scores for each industrial asset of the nominal population, the statistical distribution extending between a maximal nominal deviation score and a minimal nominal deviation score for each industrial asset of the nominal population for each of the potential frequency-parameter pairings;
determining, via the controller, a nominal score range extending between the maximal nominal deviation score and the minimal nominal deviation score of the first plurality of historical power spectral densities, wherein the nominal score range corresponds to a nominal operating state of the nominal population of the asset family at the at least one frequency band;
determining, via the controller, a plurality of fault deviation scores for each historical power spectral density of the second plurality of historical power spectral densities of each industrial asset of the fault population relative to the first plurality of historical power spectral densities, wherein the plurality of fault deviation scores is determined for each of the potential frequency-parameter pairings;
determining, via the controller, the statistical distribution of the plurality of fault deviation scores for each industrial asset of the fault population, the statistical distribution extending between a maximal fault deviation score and a minimal fault deviation score for each industrial asset of the fault population for each of the potential frequency-parameter for pairings; and
generating, via the controller, a detectability threshold for each of the plurality of frequency-parameter pairings based on the maximal nominal deviation score of at least one power spectral density of the nominal population.

8. The method of claim 7, wherein determining the plurality of frequency-parameter pairings which are indicative of the at least one fault condition further comprises:
determining, via the controller, a first distribution of the pluralities of nominal deviation scores for each of the potential frequency-parameter for pairings;
determining, via the controller, a second distribution of the pluralities of fault deviation scores for each of the potential frequency-parameter for pairings; and
determining, via the controller, a discrimination score for each of the plurality of potential frequency-parameter pairings based on a statistical difference between the first distribution and the second distribution, the discrimination score being indicative of a degree of discrimination between the nominal and fault populations of the asset family at the corresponding frequency-parameter pairing in the presence of the at least one fault condition.

9. The method of claim 8, wherein determining the plurality of frequency-parameter pairings which are indicative of the at least one fault condition further comprises:
generating, via the controller, a rank ordering of the plurality of potential frequency-parameter pairings for the at least one fault condition based, at least in part, on the discrimination score.

10. The method of claim 9, wherein determining the plurality of frequency-parameter pairings which are indicative of the at least one fault condition further comprises:
a) selecting, via the controller, a first frequency-parameter pairing of the plurality of potential frequency-parameter pairings based, at least in part, on the rank ordering for the at least one fault condition;
b) identifying, via the controller, a first portion of the fault population for which the first frequency-parameter pairing is indicative of a fault status;
c) filtering, via the controller, the first portion of the fault population so as to remove the first portion from the fault population;
d) selecting, via the controller, a second frequency-parameter pairing of the plurality of potential frequency-parameter pairings based, at least in part, on the rank ordering for the at least one fault condition;
e) identifying, via the controller, a second portion of the fault population for which the second frequency-parameter pairing is indicative of a fault status;
f) filtering, via the controller, the second portion of the fault population so as to remove the second portion from the fault population; and
g) repeating steps a)-f) until a desired percentage of the fault population demonstrating the at least one fault condition is detected by selected frequency-parameter pairings.

11. The method of claim 9, wherein the plurality of potential frequency-parameter pairings have a plurality of bandwidth combinations for each parameter of the plurality of parameters, and wherein generating the rank ordering further comprises:
determining, via the controller, the discrimination score for each of the plurality of bandwidth combinations for each parameter.

12. The method of claim 9, wherein determining the fault probability for the industrial asset further comprises:
determining, via the controller, a nominal distribution score for each industrial asset of the nominal population for each of the plurality of frequency-parameter pairings, the nominal distribution score being indicative of a distribution of the nominal deviation scores for each industrial asset of the nominal population within the nominal score range for each of the plurality of frequency-parameter pairings;
determining, via the controller, a multi-variate nominal distribution score for each industrial asset of the nominal population based, at least in part, on the nominal distribution score for each of the plurality of frequency-parameter pairings;
implementing, via the controller, a probabilistic model to determine a multi-variate distribution of the industrial assets of the nominal population based on the corresponding multi-variate nominal distribution scores; and
determining, via the controller, a fault-probability profile for the asset family based on the probabilistic model.

13. The method of claim 12, further comprising:
establishing the fault threshold via a fitting of a receiver-operating-characteristic curve (ROC-curve) to a distribution of the industrial assets of the fault population relative to the industrial assets of the nominal population.

14. The method of claim 12, wherein the plurality of frequency-parameter pairings comprises at least three frequency-parameter pairings, and wherein the fault-probability profile comprises at least a three-dimensional fault-probability profile.

15. The method of claim 1, wherein the industrial asset comprises a wind turbine.

16. A system for controlling an industrial asset of an asset family, wherein the asset family comprises a plurality of industrial assets, the system comprising:
at least one sensor operably coupled to the industrial asset; and
a controller communicatively coupled to the at least one sensor, the controller comprising at least one processor configured to perform a plurality of operations, the plurality of operations comprising:
determining a plurality of frequency-parameter pairings corresponding to at least one power spectral density of the industrial asset, each frequency-parameter pairing comprising an energy-level distribution for a parameter of the industrial asset across a plurality of frequency intervals of a portion of the at least one power spectral density,
determining a deviation score for each of the plurality of frequency-parameter pairings, wherein each of the deviation scores is indicative of a magnitude difference between the energy-level distribution of each frequency-parameter pairing and a corresponding energy-level distribution of a nominal frequency-parameter pairing of the asset family,
determining a multi-variate anomaly score based, at least in part, on the deviation scores,
determining a fault probability for the industrial asset based, at least in part, on the multi-variate anomaly score, and
implementing a control action based on the fault probability exceeding a fault threshold.

17. The system of claim 16, wherein determining the plurality of frequency-parameter pairings further comprises:
receiving a plurality of time-series observations from the at least one sensor, the plurality of time-series observations corresponding to a parameter of the industrial asset;
converting the plurality of time-series observations into the least one power spectral density of the industrial asset, wherein the at least one power spectral density comprises a range of energy levels at each of the plurality of frequency intervals of the at least one power spectral density, the range of energy levels being defined between a maximal energy level and a minimal energy level of the parameter at each frequency interval and being indicative of an energy level of the parameter at each frequency interval for a plurality of operating conditions of the industrial asset; and
identifying at least one frequency band of the plurality of frequency intervals at which the power spectral density of the industrial asset deviates from the corresponding power spectral density for the asset family at the at least one frequency band.

18. The system of claim 16, wherein determining the plurality of frequency-parameter pairings further comprises:
receiving a training data set comprising a first plurality of historical power spectral densities corresponding to a nominal population of the asset family and a second plurality of historical power spectral densities corresponding to a fault population of the asset family, wherein the first plurality of historical power spectral densities is indicative of a nominal operating condition for a plurality of parameters, and wherein the second plurality of historical power spectral densities is indicative of at least one fault condition for the plurality of parameters;
generating a fault-detection model configured to determine the plurality of frequency-parameter pairings which are indicative of the at least one fault condition, the plurality of frequency-parameter pairings being determined from a plurality of potential frequency-parameter pairings for the first and second pluralities of historical power spectral densities; and
training the fault-detection model via the training data set so as to determine the plurality of frequency-parameter pairings indicative of the at least one fault condition.

19. The system of claim 18, wherein determining the fault probability for the industrial asset further comprises:
determining a nominal distribution score for each industrial asset of the nominal population for each of the plurality of frequency-parameter pairings, the nominal distribution score being indicative of a distribution of the nominal deviation scores for each industrial asset of the nominal population within the nominal score range for each of the plurality of frequency-parameter pairings;
determining a multi-variate nominal distribution score for each industrial asset of the nominal population based, at least in part, on the nominal distribution score for each of the plurality of frequency-parameter pairings;
implementing a probabilistic model to determine a multi-variate distribution of the industrial assets of the nominal population based on the corresponding multi-variate nominal distribution scores; and
determining a fault-probability profile for the asset family based on the probabilistic model.

20. The system of claim 19, further comprising:
fitting a receiver-operating-characteristic curve (ROC-curve) to a mean distance of a distribution of the industrial assets of the fault population relative to the multi-variate distribution of the industrial assets of the nominal population as indicated by the fault-probability profile for the asset family, wherein the ROC-curve corresponds to the fault threshold.
